(19) United States
(12) Patent Application Publication
(10) Pub. No.: US 2006/0125054 A1
(43) Pub. Date: Jun. 15, 2006

(54) Electrostatic discharge protection circuit using zener triggered silicon controlled rectifier

(75) Inventors: Kwi Dong Kim, Daejeon (KR); Chong Ki Kwon, Daejeon (KR); Jong Dae Kim, Daejeon (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Electronics and Telecommunications Research Institute

(21) Appl. No.: 11/302,596

(22) Filed: Dec. 13, 2005

(30) Foreign Application Priority Data
Dec. 14, 2004 (KR) 2004-105732
May 11, 2005 (KR) 2005-39175

(51) Int. Cl. H01L 29/167

(52) U.S. Cl. 257/607

(57) ABSTRACT

Provided is an electrostatic discharge (ESD) protection circuit using a silicon controlled rectifier (SCR), which is applied to a semiconductor integrated circuit (IC). The ESD protection circuit using an SCR includes: a semiconductor substrate including a first well and a second well; first and second heavily doped regions disposed in an upper portion of the first well; third and fourth heavily doped regions disposed in an upper portion of the second well; a fifth heavily doped region disposed at an interface between the first and second wells; a sixth heavily doped region disposed beside the fifth heavily doped region in the upper portion of the second well; a first overload preventing unit having a drain connected to the sixth heavily doped region, a source connected to the first and second heavily doped regions, and a gate connected to the first and second heavily doped regions through a first resistor; and a second overload preventing unit having a drain connected to the fifth heavily doped region, a source connected to the third and fourth heavily doped regions, and a gate connected to the third and fourth heavily doped regions through a second resistor.

### CROSS-REFERENCE TO RELATED APPLICATION

This application claims priority to and the benefit of Korean Patent Application No. 2004-105732, filed Dec. 14, 2004 and Korean Patent Application No. 2005-39175, filed May 11, 2005, the disclosure of which is incorporated herein by reference in its entirety.

### BACKGROUND

1. Field of the Invention

The present invention relates to an electrostatic discharge (ESD) protection circuit for a low-voltage circuit, which is applied to a semiconductor integrated circuit (IC), and more specifically, to an ESD protection circuit using a silicon controlled rectifier (SCR).

2. Discussion of Related Art

An electrostatic discharge (ESD) phenomenon, which causes the instantaneous application of a high voltage due to static electricity that is induced by contact with a human body, frequently occurs during the fabrication or use of semiconductor components or electronic products. When a high voltage is applied to a semiconductor integrated circuit (IC) due to the ESD phenomenon, the semiconductor IC may be adversely affected or incapable of functions. For example, a thin insulating layer may be broken. Accordingly, the semiconductor IC should be designed in due consideration of the ESD phenomenon.

Above all, when a complementary metal-oxide-semiconductor (CMOS), which is very susceptible to a high voltage, is fabricated on the scale of deep submicrons (DSM), a gate oxide layer is further thinned out. Therefore, it is probable that damage caused by the ESD phenomenon will become greater.

In general, an ESD protection circuit, which is applied to a semiconductor IC, is configured such that a high voltage or current input through an input terminal is discharged through a discharge path before it is sent to core circuits.

FIG. 1 is a cross-sectional view of a gate grounded NMOS (ggNMOS) device, which is an example of a conventional ESD protection circuit.

Referring to FIG. 1, lightly doped drain (LDD)-type n⁺ source 2 and drain 3 are formed in a p-type semiconductor substrate 1, and a gate 5 is formed on the semiconductor substrate 1 between the source 2 and the drain 3 and electrically insulated from the semiconductor substrate 1 by a gate insulating layer 4. A silicide layer 6 is formed on the surfaces of the gate 5, the source 2, and the drain 3 to reduce contact resistance, and the source 2 and the drain 3 are connected to input/output pads S and D. In the above-described NMOS transistor, all the terminals except the drain 3 (i.e., the gate 5 and the source 2) are connected to a ground, and an ESD pulse is applied through the input/output pad D connected to the drain 3.

An ESD protection circuit, which is used in the above-described ggNMOS device, is comprised of an NPN bipolar transistor Q1 that includes the source 2, the semiconductor substrate 1, and the drain 3, and a substrate resistor R1.

Such an ESD protection circuit has a good ESD protection effect owing to low trigger voltage and snapback characteristics. However, because the ESD protection circuit has insufficient current discharge capacity, its size should be enlarged to obtain a reliable ESD protection effect. The larger the ESD protection circuit is, the greater a parasitic capacitance element is. Therefore, the ESD protection circuit has degraded driving capability and cannot be highly integrated.

In recent years, an ESD protection circuit using a silicon controlled rectifier (SCR) has been developed. As is known, the SCR has an excellent ESD protection function and includes only a small parasitic capacitance element. In addition, the SCR has attracted considerable attention as a device appropriate for high-speed small-sized semiconductor ICs.

FIG. 2 is a cross-sectional view of a conventional ESD protection circuit using an SCR, and FIG. 3 is an equivalent circuit diagram of the ESD protection circuit shown in FIG. 2.

Referring to FIG. 2 and FIG. 3, a p-well 12 is formed in a p⁺-type semiconductor substrate 11, and an n-well 13 is formed in a predetermined portion of the p-well 12. An n⁺ region 14 and a p⁺ region 15 are formed in an upper portion of the n-well 13, and an n⁺ region 16 and a p⁺ region 17 are formed in an upper portion of the p-well 12. The n⁺ region 14 and the p⁺ region 15 are used as an anode A, and the n⁺ region 16 and the p⁺ region 17 are used as a cathode C.

Accordingly, the p⁺ region 15, the n-well 13, and the p-well 12 constitute an NPN bipolar transistor Q 11, and the n-well 13, the p-well 12, and the n⁺ region 16 constitute a PNP bipolar transistor Q12. The SCR is comprised of the NPN bipolar transistor Q11 and the PNP bipolar transistor Q12. A resistor R11 is a resistance element of the n-well 13, a resistor R12 is a resistance element of the p⁺-type semiconductor substrate 11, and a resistor R13 is a resistance element of the p-well 12.

The above-described ESD protection circuit using the SCR has even greater discharge capacity than the ggNMOS device because the NPN and PNP bipolar transistors Q11 and Q12 form a positive feedback loop. Therefore, the ESD protection circuit using the SCR can obtain an effective ESD protection effect even with a small area and is suitable for a high-frequency device by minimizing a parasitic capacitance element.

However, since a trigger (driving) voltage of the SCR is as high as about 20 to 30 V, when it is applied to a metal oxide semiconductor field effect transistor (MOSFET) that is fabricated on the DSM scale, it is difficult to effectively remove an ESD pulse before a gate oxide layer is broken. In other words, an IC that is fabricated on the DSM scale cannot endure even a voltage that is far lower than 20 V. For this reason, when the ESD pulse is applied to the IC, the gate oxide layer of the MOSFET that constitutes a core circuit may be broken.

### SUMMARY OF THE INVENTION

The present invention is directed to an electrostatic discharge (ESD) protection circuit using a silicon controlled rectifier (SCR), which can be applied to an integrated circuit (IC) of a highly integrated semiconductor device that is fabricated on the scale of deep submicrons (DSM).

In addition, the present invention provides an ESD protection circuit using an SCR, which is used for a low-voltage circuit and requires a low trigger voltage.

One aspect of the present invention is to provide an ESD protection circuit using an SCR. The ESD protection circuit includes: a semiconductor substrate including a first well and a second well; first and second heavily doped regions disposed in an upper portion of the first well; third and fourth heavily doped regions disposed in an upper portion of the second well; a fifth heavily doped region disposed at an interface between the first and second wells; a sixth heavily doped region disposed beside the fifth heavily doped region in the upper portion of the second well; a first overload preventing unit having a drain connected to the sixth heavily doped region, a source connected to the first and second heavily doped regions, and a gate connected to the first and second heavily doped regions through a first resistor; and a second overload preventing unit having a drain connected to the fifth heavily doped region, a source connected to the third and fourth heavily doped regions, and a gate connected to the third and fourth heavily doped regions through a second resistor.

The first well and the first, third, and fifth heavily doped regions may be doped with impurity ions of a first conductivity type, and the second well and the second, fourth, and sixth heavily doped regions may be doped with impurity ions of a second conductivity type.

Another aspect of the present invention is to provide an ESD protection circuit using an SCR. The ESD protection circuit includes: a first transistor having an emitter connected to a first terminal; a first resistor connected between a collector of the first transistor and a second terminal; a second resistor connected between the first terminal and a base of the first transistor; a second transistor connected between the base of the first transistor and the second terminal and having a base connected to the collector of the first transistor; a zener junction diode having an anode and a cathode connected to the base of the second transistor and the base of the first transistor, respectively; third and fourth resistors connected to the first and second terminals, respectively; a third transistor having a drain and a source connected to the anode of the zener junction diode and the first terminal, respectively, and having a base connected to the third resistor; and a fourth transistor having a drain and a source connected to the cathode of the zener junction diode and the second terminal, respectively, and having a base connected to the fourth resistor.

The first terminal may be connected to an input and output pads, and the second terminal may be connected to a ground.

The first transistor may be a PNP bipolar transistor, the second transistor may be an NPN bipolar transistor, the third transistor may be a PMOS transistor, and the fourth transistor may be an NMOS transistor.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a cross-sectional view of an example of a conventional electrostatic discharge (ESD) protection circuit;

FIG. 2 is a cross-sectional view of a conventional ESD protection circuit using a silicon controlled rectifier (SCR);

FIG. 3 is an equivalent circuit diagram of the ESD protection circuit shown in FIG. 2;

FIG. 4 is a cross-sectional view of an ESD protection circuit using an SCR according to an exemplary embodiment of the present invention;

FIG. 5 is an equivalent circuit diagram of the ESD protection circuit shown in FIG. 4; and

FIG. 6 is a graph of current Ia with respect to anode voltage Va.

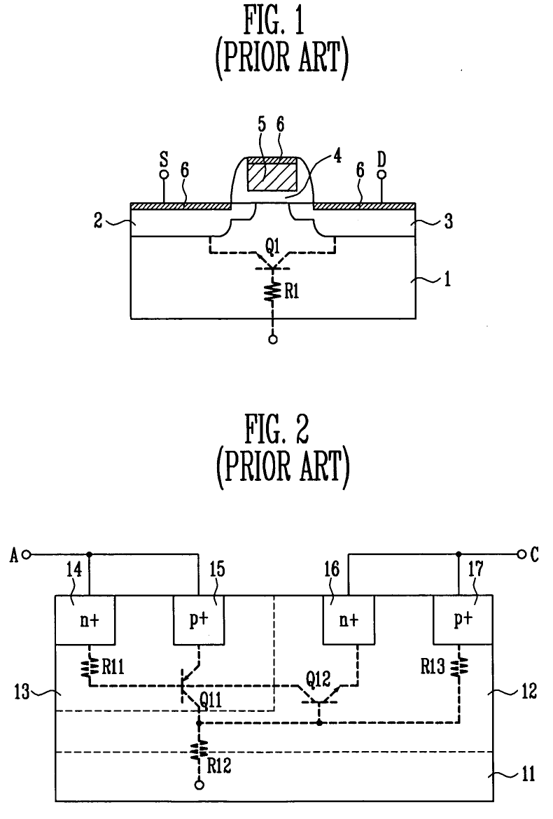

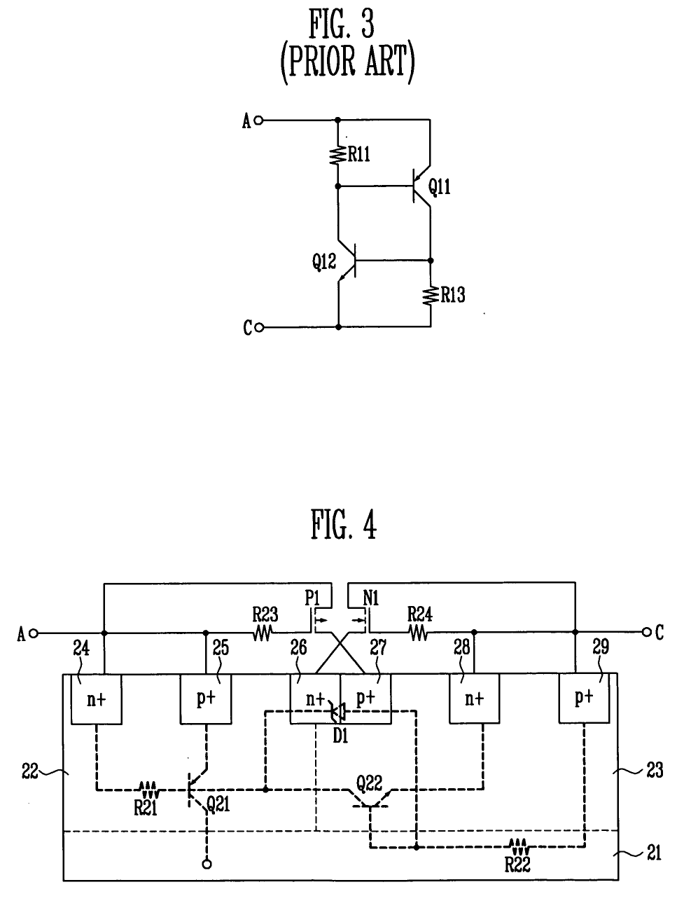

### DETAILED DESCRIPTION OF EXEMPLARY EMBODIMENTS

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art.

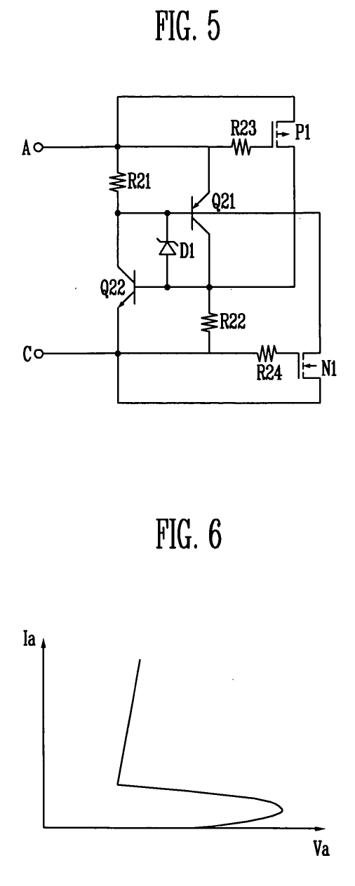

FIG. 4 is a cross-sectional view of an electrostatic discharge (ESD) protection circuit using a silicon controlled rectifier (SCR) according to an exemplary embodiment of the present invention, and FIG. 5 is an equivalent circuit diagram of the ESD protection circuit shown in FIG. 4.

An n-well 22 and a p-well 23 are formed in a p-type semiconductor substrate 21. An n⁺ region 24 and a p⁺ region 25 are formed in an upper portion of the n-well 22, and an n⁺ region 28 and a p⁺ region 29 are formed in an upper portion of the p-well 23. In addition, an n⁺ region 26 is formed in an upper portion of an interface between the n-well 22 and the p-well 23, and a p⁺ region 27 is formed beside the n⁺ region 26 in the upper portion of the p-well 23. The n⁺ region 24 and the p⁺ region 25 are used as an anode A, and the n⁺ region 28 and the p⁺ region 29 are used as a cathode C.

Accordingly, the p⁺ region 25, the n-well 22, and the p-type semiconductor substrate 21 constitute a PNP bipolar transistor Q21, and the n-well 22, the p-well 23, and the n⁺ region 28 constitute an NPN bipolar transistor Q22. An SCR is comprised of the PNP bipolar transistor Q21 and the NPN bipolar transistor Q22. A zener junction diode D1, which includes the p⁺ region 27 and the n⁺ region 26, is connected to the SCR. A resistor R21 is a resistance element of the n-well 22, and a resistor R22 is a resistance element of the p-type semiconductor substrate 21. The resistors R21 and R22 provide biases of the PNP bipolar transistor Q21 and the NPN bipolar transistor Q22.

In addition, a PMOS transistor P1, which has a gate connected to the n⁺ region 24 and the p⁺ region 25 through a resistor R23, is connected between the p⁺ region 27 and the n⁺ region 24/the p⁺ region 25. An NMOS transistor N1, which has a gate connected to the n⁺ region 28 and the p⁺ region 29 through a resistor R24, is connected between the n⁺ region 26 and the n⁺ region 28/the p⁺ region 29.

Since the SCR changes from a high impedance to a low impedance, it is typically employed in power devices. However, the SCR can be appropriately designed to produce a good ESD protection effect.

In FIG. 4, the SCR, which is comprised of the PNP bipolar transistor Q21 and the NPN bipolar transistor Q22, has a simple PNPN structure. The p⁺ region 25 formed in the n-well 22 is used as the anode A, and the n⁺ region 28 formed in the p-well 23 is used as the cathode C. In this case, the anode A may be connected to the n⁺ region 24 formed in the n-well 22, and the cathode C may be connected to the p⁺ region 29 formed in the p-well 23. That is, the PNP bipolar transistor Q21 is comprised of the anode A for an emitter, the n-well 22 for a base, and the p-type semiconductor substrate 21 for a collector, and the NPN bipolar transistor Q22 is comprised of the cathode C for an emitter, the p-well 23 for a base, and the n-well 22 for a collector.

When a predetermined voltage Vc, for example, a power supply voltage, is applied to the n-well 22, a voltage Va that is higher than or equal to the voltage Vc is applied to the anode A, and the cathode C and the p-well 23 are connected to a ground, an anode current Ia varies with the voltage Va applied to the anode A as shown in FIG. 6.

Hereinafter, the operation of the above-described ESD protection circuit using the SCR according to the present invention will be described.

When an ESD pulse is input through an input pad and the voltage Va at the anode A is higher than the voltage Vc, the p⁺ region 25 and the n-well 22 are biased forward so that a current path is formed between the p⁺ region 25 and the p-type semiconductor substrate 21. In this case, the emitter and base of the PNP bipolar transistor Q21 are biased forward due to a voltage drop caused by the resistor R21 of the n-well 22, thus the PNP bipolar transistor Q21 is turned on to permit a current to pass through the p-type semiconductor substrate 21. As a result, holes are supplied from the anode A and transported to the cathode C connected to the ground through the p-type semiconductor substrate 21, which acts as a collector of the PNP bipolar transistor Q21.

In addition, when the NPN bipolar transistor Q22 is turned on due to a voltage drop caused by the resistor R22 of the p-type semiconductor substrate 21, electrons are supplied from the cathode C connected to the ground and transported to the anode A through the NPN bipolar transistor Q22.

As the electrons are transported as described above, the voltage drop caused by the resistor R21 is further increased so that a positive loop is formed to induce sufficient discharge. Specifically, since the NPN bipolar transistor Q22 is biased forward due to a current that is supplied to the cathode C through the PNP bipolar transistor Q21, it is not necessary to hold the forward biasing of the PNP bipolar transistor Q21 any more. As a result, the voltage Va at the anode A is minimized. In this case, the minimized voltage Va at the anode A is referred to as a holding voltage, which depends on a current that passes through the PNP bipolar transistor Q21.

The SCR, which is comprised of the PNP bipolar transistor Q21 and the NPN bipolar transistor Q22, can be maintained in a latch mode by satisfying the following Equation 1:
βₙₚₙ·βₚₙₚ≧1 (1),

wherein βₙₚₙ and βₚₙₚ denote current gains of the NPN bipolar transistor Q22 and the PNP bipolar transistor Q21, respectively.

In the SCR, I_{trig} and Vₕ may be given as two important variables. I_{trig} depends on an element of the resistor R22 of the p-type semiconductor substrate 21. The element of the resistor R22 is determined by a thickness L and concentration of the p-type semiconductor substrate 21. In addition, Vₕ is greatly affected by the thickness L and the element of the resistor R22 of the n-well 22. In general, a complementary metal-oxide-semiconductor (CMOS) device that is fabricated on the scale of deep submicrons (DSM) has a voltage Vₕ of 2 to 5 V.

In order to trigger the SCR, the n-well 22 and the p⁺ region 25 need to have an avalanche breakdown, and a trigger voltage is defined as a breakdown voltage of the n-well 22 and the p-type semiconductor substrate 21.

The ESD protection circuit according to the present invention includes a zener junction diode D1, which is connected to gates of the PNP bipolar transistor Q21 and the NPN bipolar transistor Q22 that constitute the SCR. Since the zener junction diode D1 including the p⁺ region 27 and the n⁺ region 26 that are heavily doped regions has a narrow bandgap, it has a breakdown voltage of about 5 to 6 V lower than a typical pn junction diode. In addition, the zener junction diode D1 includes a depletion layer that is mostly formed in the p-well 23. Therefore, the SCR of the present invention can reduce a trigger voltage lower than a conventional SCR.

That is, when an ESD pulse is applied to the anode A connected to the input pad, electron hole pairs are produced at a low voltage of 6 V or less by the zener junction diode D1 with a low breakdown voltage and injected into the n-well 22 and the p-well 23. The transported electrons and holes lead the PNP bipolar transistor Q21 and the NPN bipolar transistor Q22 to operate forward, thereby lowering a trigger voltage.

In addition, in the ESD protection circuit according to the present invention, the PMOS transistor P1 is connected between an anode of the zener junction diode D1 and the anode A, and the NMOS transistor N1 is connected between a cathode of the zener junction diode D1 and the cathode C. Accordingly, an overload (overcurrent) caused by a negative ESD pulse is prevented due to the PMOS transistor P1, which has a drain connected to the anode of the zener junction diode D1, a source connected to the anode A, and a gate connected to the anode A and the n⁺ region 24 and the p⁺ region 25 of the n-well 22 through the resistor R23. In addition, an overload (overcurrent) caused by a positive ESD pulse is prevented due to the NMOS transistor N1, which has a drain connected to the cathode of the zener junction diode D1, a source connected to the cathode C, and a gate connected to the cathode C and the n⁺ region and the p⁺ region 29 of the p-well 23 through the resistor R24.

If there are not the PMOS transistor P1 and the NMOS transistor N1, a voltage difference Vh between the anode A and the cathode C should be greater than the breakdown voltage of the zener junction diode D1 to form a discharge path. However, if the PMOS transistor P1 and the NMOS transistor N1 are added, the voltage difference Vₕ between the anode A and the cathode C may be less than the breakdown voltage of the zener junction diode D1 to form a discharge path. In other words, after a discharge path is primarily formed through the PMOS transistor P1 and the NMOS transistor N1 having low threshold voltages, when the voltage drop caused by the resistor R21 happens, another discharge path is formed through the PNP bipolar transistor Q21 and the NPN bipolar transistor Q22 as described above.

Nowadays, with the introduction of DSM-scale fabrication to semiconductor devices, there is a tendency to decrease the driving voltage of the semiconductor devices and the thickness of an insulating layer. Accordingly, it is expected that damage caused by an ESD phenomenon will become greater. To solve this problem, it is necessary to develop an ESD protection circuit that operates at a low voltage and requires a low trigger voltage.

A conventional ESD protection circuit using an SCR has a good ESD protection effect but cannot be applied to a highly integrated device owing to a high trigger voltage. Therefore, in the present invention, a zener junction diode is connected between gates of a PNP bipolar transistor and an NPN bipolar transistor that constitute an SCR, thus a trigger voltage of the SCR can be reduced. In addition, a PMOS transistor is connected to an emitter and gate of the PNP bipolar transistor and an anode of the zener junction diode, and an NMOS transistor is connected to an emitter and gate of the NPN bipolar transistor and a cathode of the zener junction diode, so that when an ESD pulse is input through an input pad, a discharge path can be formed. In conclusion, an ESD protection circuit that has a low trigger voltage and great discharge capacity can be easily formed in a small area.

The ESD protection circuit of the present invention can be applied to nanoscale semiconductor integrated circuits (ICs).

In the drawings and specification, there have been disclosed typical exemplary embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. An electrostatic discharge protection circuit using a silicon controlled rectifier, the circuit comprising:
a semiconductor substrate including a first well and a second well;
first and second heavily doped regions disposed in an upper portion of the first well;
third and fourth heavily doped regions disposed in an upper portion of the second well;
a fifth heavily doped region disposed at an interface between the first and second wells;
a sixth heavily doped region disposed beside the fifth heavily doped region in the upper portion of the second well;
a first overload preventing unit having a drain connected to the sixth heavily doped region, a source connected to the first and second heavily doped regions, and a gate connected to the first and second heavily doped regions through a first resistor; and
a second overload preventing unit having a drain connected to the fifth heavily doped region, a source connected to the third and fourth heavily doped regions, and a gate connected to the third and fourth heavily doped regions through a second resistor.

2. The circuit according to claim 1, wherein the first well and the first, third, and fifth heavily doped regions are doped with impurity ions of a first conductivity type, and the second well and the second, fourth, and sixth heavily doped regions are doped with impurity ions of a second conductivity type.

3. The circuit according to claim 2, wherein the first conductivity type is an n type, and the second conductivity type is a p type.

4. The circuit according to claim 1, wherein the first overload preventing unit is comprised of a PMOS transistor, and the second overload preventing unit is comprised of an NMOS transistor.

5. The circuit according to claim 1, wherein the first and second heavily doped regions are connected to input and output pads, and the third and fourth heavily doped regions are connected to a ground.

6. An electrostatic discharge protection circuit using a silicon controlled rectifier, the circuit comprising:
a first transistor having an emitter connected to a first terminal;
a first resistor connected between a collector of the first transistor and a second terminal;
a second resistor connected between the first terminal and a base of the first transistor;
a second transistor connected between the base of the first transistor and the second terminal and having a base connected to the collector of the first transistor;
a zener junction diode having an anode and a cathode connected to the base of the second transistor and the base of the first transistor, respectively;
third and fourth resistors connected to the first and second terminals, respectively;
a third transistor having a drain and a source connected to the anode of the zener junction diode and the first terminal respectively, and having a base connected to the third resistor; and
a fourth transistor having a drain and a source connected to the cathode of the zener junction diode and the second terminal respectively, and having a base connected to the fourth resistor.

7. The circuit according to claim 6, wherein the first terminal is connected to an input and output pads, and the second terminal is connected to a ground.

8. The circuit according to claim 6, wherein the first transistor is a PNP bipolar transistor, the second transistor is an NPN bipolar transistor, the third transistor is a PMOS transistor, and the fourth transistor is an NMOS transistor.
